(19) United States
(12) Patent Application Publication
(10) Pub. No.: US 2026/0231709 A1
(43) Pub. Date: Aug. 6, 2026

(54) ELECTRONIC DEVICE AND METHOD OF SINGULATING

(71) Applicant: TEXAS INSTRUMENTS INCORPORATED, DALLAS, TX (US)

(72) Inventors: MICHAEL TODD WYANT, DALLAS, TX (US); QI SEN GUO, CHENGDU (CN); SHAN HE, CHENGDU (CN); LIU QIANG LIAO, CHENGDU (CN); DANNY L. BRIJA, ALLEN, TX (US)

(21) Appl. No.: 19/038,221

(22) Filed: Jan. 27, 2025

(51) Int. Cl. H10P 54/00; H10P 72/70; H10W 70/40; H10W 72/00; H10W 74/01; H10W 74/10; H10W 90/00

(52) U.S. Cl. CPC H10P 54/00; H10P 72/7402; H10W 70/415; H10W 72/884; H10W 74/01; H10W 74/129; H10W 90/736; H10W 90/756

(57) ABSTRACT

An electronic device and method of fabricating the electronic device are provided where the method includes attaching an electronic device layer on a first surface of a substrate and forming first openings in only the electronic device layer to form individual dies. A back grinding process is performed on a second surface of substrate and the substrate is placed on an isolation layer. Second openings are formed in the substrate and the isolation layer to form die assemblies comprising the individual dies, the substrate, and the isolation layer. The die assemblies are placed on a leadframe and a mold compound is formed over the die assemblies.

### TECHNICAL FIELD

The present disclosure relates to electronic devices, and more specifically to an electronic device and method of providing protection for die attach film plasma dicing.

### BACKGROUND

Singulating dies attached to a wafer (e.g., silicon wafer) requires a dicing process such as a mechanical process referred to as blade dicing or a process that uses a laser referred to as laser dicing (e.g., plasma laser singulation). Blade dicing employs a saw (e.g., diamond saw) that cuts along scribe lines that separate each die eventually cutting through the wafer. Laser dicing uses a focused non-contact laser beam to separate the dies and the wafer. This is accomplished by either feeding the laser over the front side of the thinned wafer or repeatedly irradiating the silicon wafer until a cut in the tape is made. Although both processes are still in use today, both processes create silicon and metal particles during separation that can become lodged in the separated dies, which in turn can cause performance issues.

### SUMMARY

In a described example, a method includes forming an electronic device layer on a first surface of a substrate and forming first openings in only the electronic device layer to form individual dies. A back grinding process is performed on a second surface of substrate and the substrate is placed on an isolation layer. Second openings are formed in the substrate and the isolation layer to form die assemblies comprising the individual dies, the substrate, and the isolation layer. The die assemblies are placed on a leadframe and a mold compound is formed over the die assemblies.

In another described example, an electronic device includes a leadframe having inner leads. A die assembly is attached to the inner leads, where the die assembly includes a substrate, a die attached to a first surface of the substrate, and an isolation layer attached to a second surface of the substrate, the die having a taper extending from an active surface of the die down each side of the die. A mold compound encapsulates the die assembly.

### BRIEF DESCRIPTION OF THE DRAWINGS

FIGS. 1A and 1B are top and cross-sectional views respectively of an example electronic device.

FIG. 1C is cross-sectional views of another example electronic device.

FIG. 2 is a block diagram flow chart explaining a fabrication process of the example electronic device of FIGS. 1A and 1B.

FIG. 3A is a top view of a substrate (e.g., wafer).

FIG. 3B illustrates a cross-sectional view of the substrate of FIG. 3A in the early stages of fabrication.

FIG. 3C illustrates a cross-sectional view of the substrate of FIG. 3B after placement of an electronic device layer on the substrate prior to singulation.

FIG. 3D illustrates a cross-sectional view of the substrate and the electronic device layer of FIG. 3B after undergoing formation and patterning of a first photoresist material layer.

FIG. 3E illustrates a cross-sectional view of the substrate and the electronic device layer of FIG. 3D after undergoing a first dicing process.

FIG. 3F illustrates a cross-sectional view of the substrate and the electronic device layer of FIG. 3E after undergoing removal of the first photoresist material layer.

FIG. 3G illustrates a cross-sectional view of the substrate and the electronic device layer of FIG. 3F after undergoing formation and patterning of a second photoresist material layer.

FIG. 3H illustrates a cross-sectional view of the substrate and the electronic device layer of FIG. 3G after undergoing a back grinding process to grind a portion of the substrate.

FIG. 3I illustrates a cross-sectional view of the substrate and the electronic device layer of FIG. 3H after placement of the substrate and dies onto a die attach film disposed in a framed substrate ring.

FIG. 3J illustrates a cross-sectional view of the substrate and the electronic device layer of FIG. 3I after undergoing a second dicing process.

FIG. 3K illustrates a cross-sectional view of the substrate and the electronic device layer of FIG. 3J after undergoing removal of the second photoresist material layer.

FIG. 3L illustrates a cross-sectional view of a die assembly after removal from the framed substrate ring of FIG. 3K and placed onto a leadframe.

FIG. 3M illustrates a cross-sectional view of the die assembly of FIG. 3L after attachment of wire bonds from the die to inner leads of the leadframe.

FIG. 3N illustrates a cross-sectional view of the die assembly of FIG. 3M after undergoing a formation of a mold compound resulting in the electronic device.

FIG. 3O illustrates a partial close-up cross-sectional view of adjacent die assemblies of FIG. 3K.

### DETAILED DESCRIPTION

Singulating dies attached to a substrate (e.g., silicon wafer) requires a dicing process such as a mechanical process referred to as blade dicing or a process that uses a laser referred to as laser dicing (e.g., plasma laser singulation). Blade dicing employs a saw (e.g., diamond saw) that cuts along scribe lines that separate each die, eventually cutting through the substrate. Laser dicing uses a focused non-contact laser beam to separate the dies and the substrate.

During either dicing process a line is scribed along a scribe line to allow for alignment of the dicing cutting tool (e.g., diamond cutting wheel, wafer saw, laser, etc.). Each scribe line, however, typically has a large width of at least 80 microns. Accordingly, the scribe lines consume a large portion of the semiconductor wafer, which limits the size of the die in an electronic device (e.g., integrated circuit (IC)). Additionally, during the mechanical sawing dicing, the wafer may splinter creating silicon and metal particles that may become embedded in an isolation layer (e.g., die attach layer) resulting in electrical leakage between the layers of the electronic device package. Similarly, during the laser dicing process, an internal crack is formed in the wafer between respective dies. The wafer is then pulled apart which also splinters thereby creating silicon and metal particles. As in the mechanical sawing dicing, these particles may become embedded in the isolation layer resulting in electrical leakage between the layers of the electronic device package.

In addition, an etching depth to dice non-singulated IC layers (e.g., substrate (e.g., wafer), electronic device (die) layer, isolation layer (die attach film), etc.) during fabrication of the IC is a function of a thickness of the photoresist material layer. In other words, the thickness of the photoresist material layer limits the etching (dicing) depth. For example, to etch (or dice) through the IC layers with scribe lines (dicing streets) of approximately 10 microns or less, openings in the photoresist material layer aligned with the scribe lines of approximately 6 microns are required. The 6 micron opening, however, limits the thickness of the photoresist material layer to approximately 14-16 microns, which is not thick enough to allow dicing of the IC layers. Specifically, during the dicing process, in order to fully dice the IC layers, since the photoresist material layer is only 14-16 microns thick, the photoresist material layer disintegrates and leaves a residue on a surface of the die layer, which contaminates the dies.

In order to fully dice through the IC layers, the thickness of the photoresist material layer should be approximately 50 microns. At this thickness, however, the photoresist material layer openings aligned with the scribe lines increases to approximately 14-16 microns. Since the scribe lines (dicing streets) are only 10 microns or less, the dies would be exposed to a laser during the laser dicing process, which would damage the dies.

Disclosed herein is an electronic device (e.g., integrated circuit (IC)) and method of fabricating the electronic device that overcomes the aforementioned disadvantages. The electronic device includes a die assembly that is disposed on contact pads of inner leads of a leadframe. Specifically, the die assembly includes an isolation layer (e.g., die attach film) to isolate the die from the leadframe, and the isolation layer is attached to the inner leads of the leadframe.

The method of fabricating the electronic device is a two-step laser dicing process (e.g., plasma laser dicing) that that employs a first photoresist material layer during a first dicing (etching) process to singulate through the electronic device layer (dies) and a second photoresist material layer during a second dicing (etching) process to singulate the remaining layers, i.e., substrate and isolation layer. This two-step process allows the scribe lines (dicing streets) to be reduced from approximately 80 microns to approximately 10 microns or less without damaging the electronic device layer. This reduction in the scribe lines facilitates larger dies to be incorporated on the wafer and ultimately in the IC. The two-step process also mitigates splintering of the substrate and the electronic device layer during singulation, which reduces waste and cost.

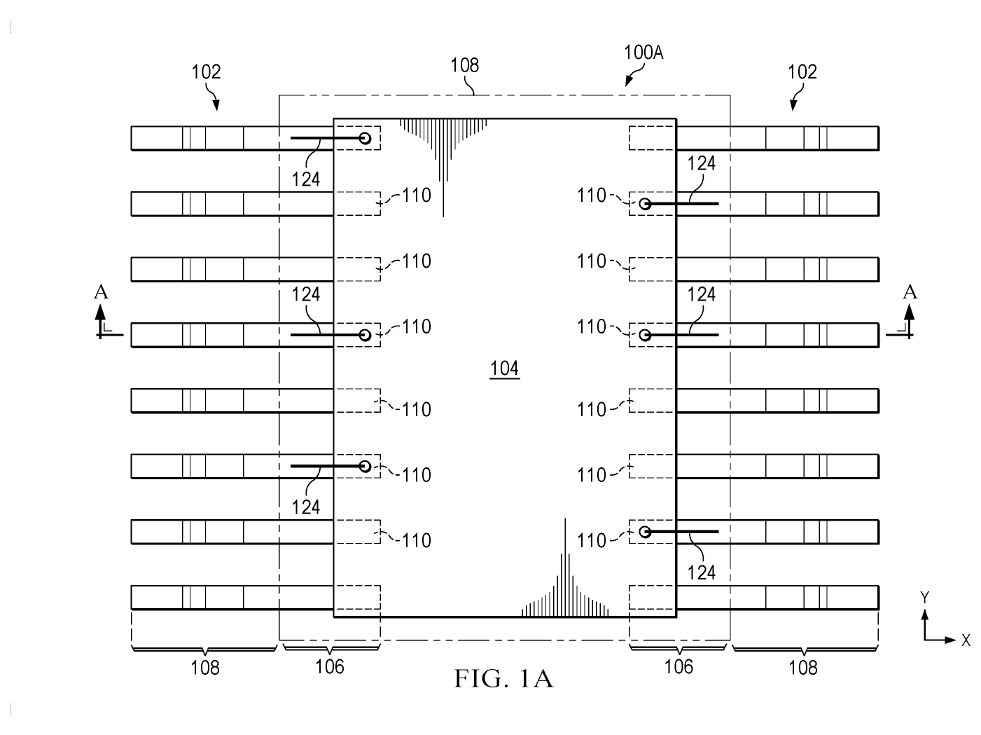

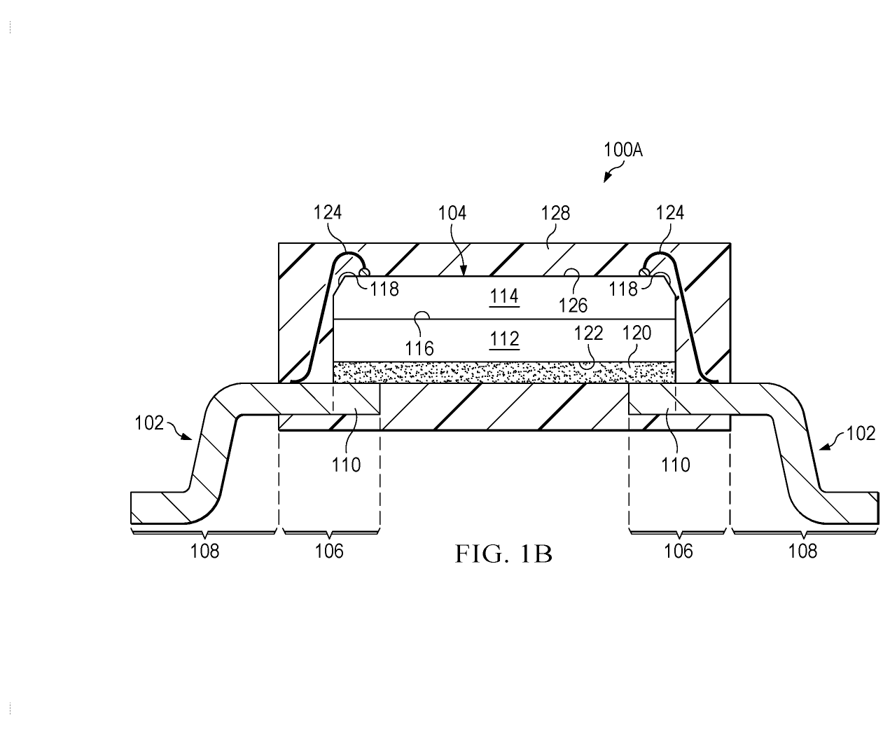

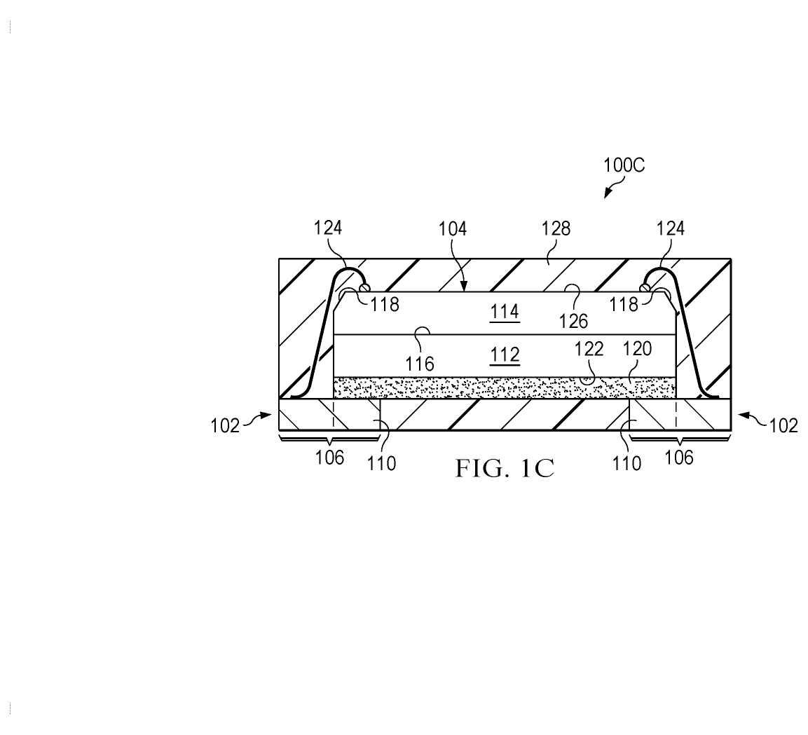

FIG. 1A is a top transparent view of an example electronic device (e.g., integrated circuit (IC)) 100A and FIG. 1B is a cross-sectional view of the example electronic device 100A of FIG. 1A taken along the line A-A. Although, the example electronic device 100A described herein and illustrated in FIGS. 1A and 1B is a leaded package, the electronic device 100A can be comprised of any type of leaded IC package including, but not limited to a small outline transistor (SOT), a small outline IC (SOIC), a dual in-line package (DIP), etc. or a non-leaded IC package including, but not limited to a land grid array (LGA), a quad-flat package (QFP), a quad-flat no-lead (QFN), etc. Although, the example electronic device 100A illustrated in FIGS. 1A and 1B is an example illustration of a leaded package, the example electronic device 100A illustrated in FIGS. 1A and 1B is for illustrative purposes only and is not intended to limit the scope of the invention.

The electronic device 100A includes a leadframe 102 and a die assembly 104. The leadframe 102 is comprised of inner (internal) leads 106 and outer (external) leads 108. Each inner lead 106 includes a die mounting pad 110 that is configured to receive the die assembly 104. The die assembly 104 is comprised of, inter alia, a substrate (e.g., silicon wafer) 112 and an electronic device layer (e.g., die) 114 disposed on a first surface 116 of the substrate 112. An outer top edge of the electronic device layer 114 includes a taper 118 that is created during the fabrication process, specifically during singulation described further below.

An isolation layer (e.g., die attach film) 120 is attached to a second surface 122 of the substrate 112 to complete the die assembly 104. The isolation layer 120 isolates (voltage isolation) the dies from the leadframe 102. A thickness of the isolation 120 depends on the voltage isolation requirements of the electronic device 100A. In one example, the thickness of the isolation layer 120 can range from approximately 40-60um. As the voltage isolation requirement increases, the thickness of the isolation layer 120 will increase. The die assembly 104 attaches to the die mounting pads 110 on each inner lead 106 via the isolation layer 120. Thus, the die assembly 104 and more specifically, the electronic device layer 114 can be configured to be larger in size in an x-y direction (see FIG. 1A) since the die assembly 104 is disposed on the die mounting pads 110 on the inner leads 106 and is not constrained to a die attach pad situated in a center of the leadframe 102. Wire bonds 124 provide an electrical connection between an active surface 126 of the electronic device layer 114 and the inner leads 106 of the leadframe 102. A mold compound 128 encapsulates the die assembly 104, the inner leads 106 including the die mounting pads 110, and the wire bonds 124.

FIG. 1C is a cross-sectional view of another example electronic device 100C. The example electronic device 100C is an example illustration of a Quad Flat No-Lead (QFN) package. The example electronic device 100C illustrated in FIG. 1C is for illustrative purposes only and is not intended to limit the scope of the invention. The electronic device 100C includes the same components as the electronic device illustrated in FIG. 1B, thus details of these components will be repeated. The exception is that the leadframe 102 of the electronic device 100C includes only inner leads 106 and does not include outer leads.

As in the example illustrated in FIG. 1B, the die assembly 104 of the electronic device 100C is disposed on the die mounting pads 110 of the inner leads 106 via the isolation layer 120. The wire bonds 124 provide an electrical connection between the active surface 126 of the electronic device layer 114 and the inner leads 106 of the leadframe 102. The mold compound 128 encapsulates the die assembly 104, the inner leads 106 including the die mounting pads 110, and the wire bonds 124. As in the example in FIGS. 1A and 1B, the die assembly 104 and more specifically, the electronic device layer 114 can be configured to be larger in size in an x-y direction (see FIG. 1A) since the die assembly 104 is disposed on the die mounting pads 110 on the inner leads 106 and is not constrained to a die attach pad situated in a center of the leadframe 102.

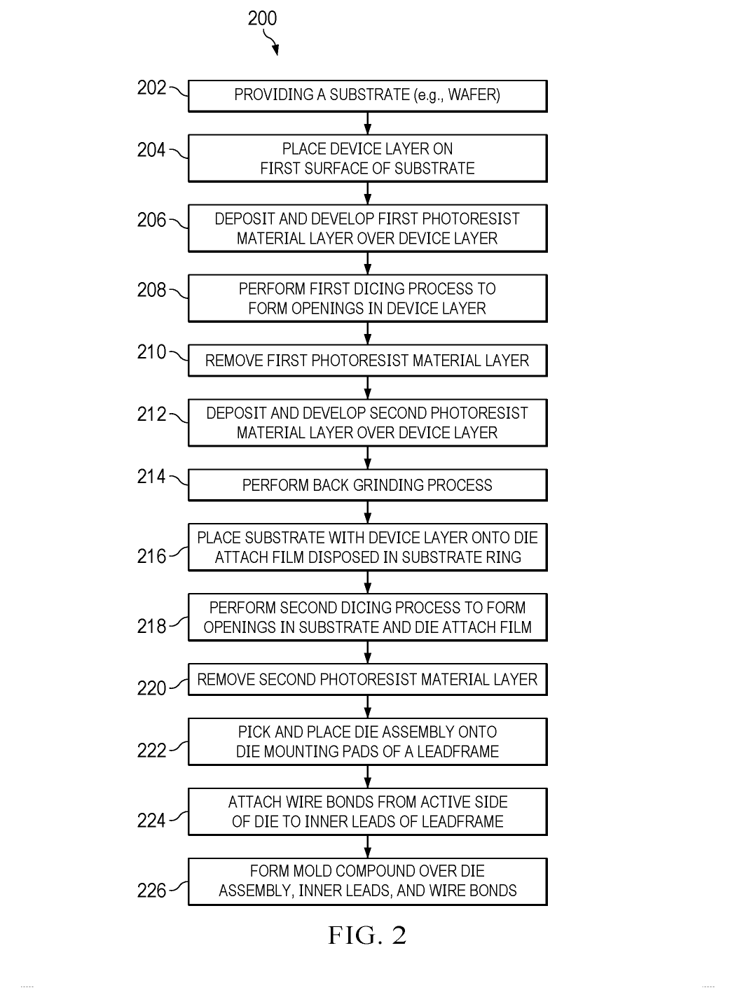

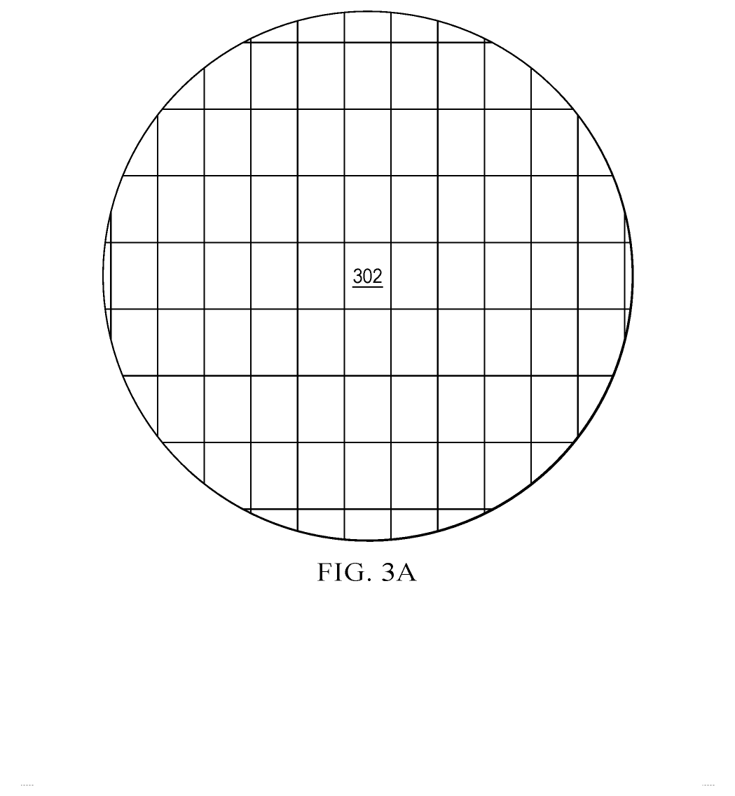

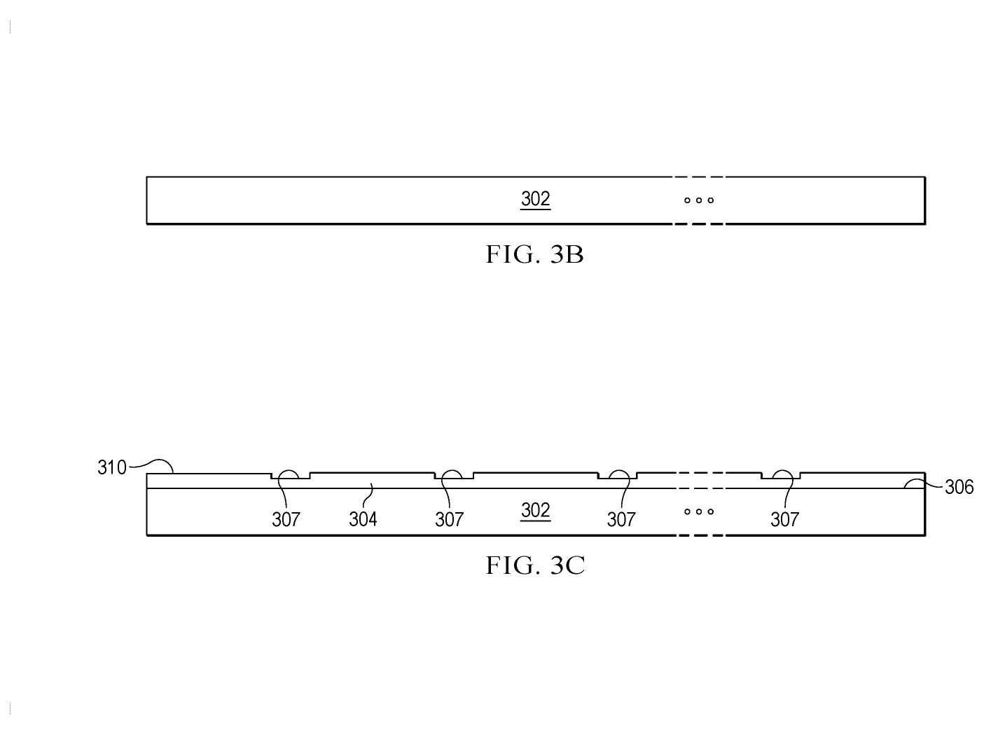

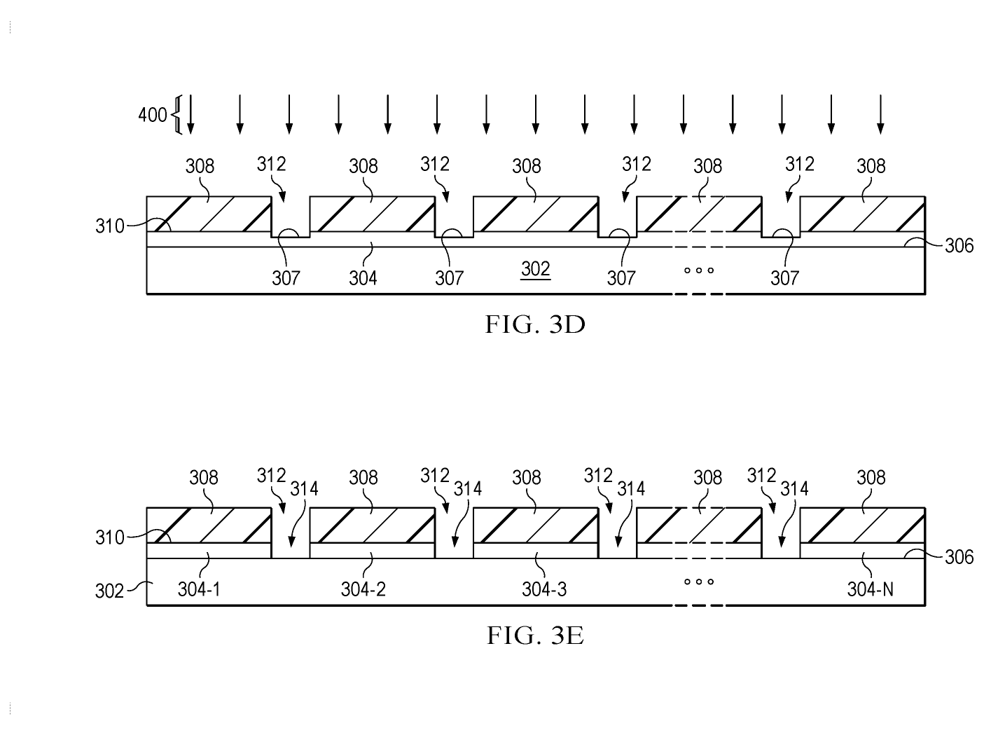

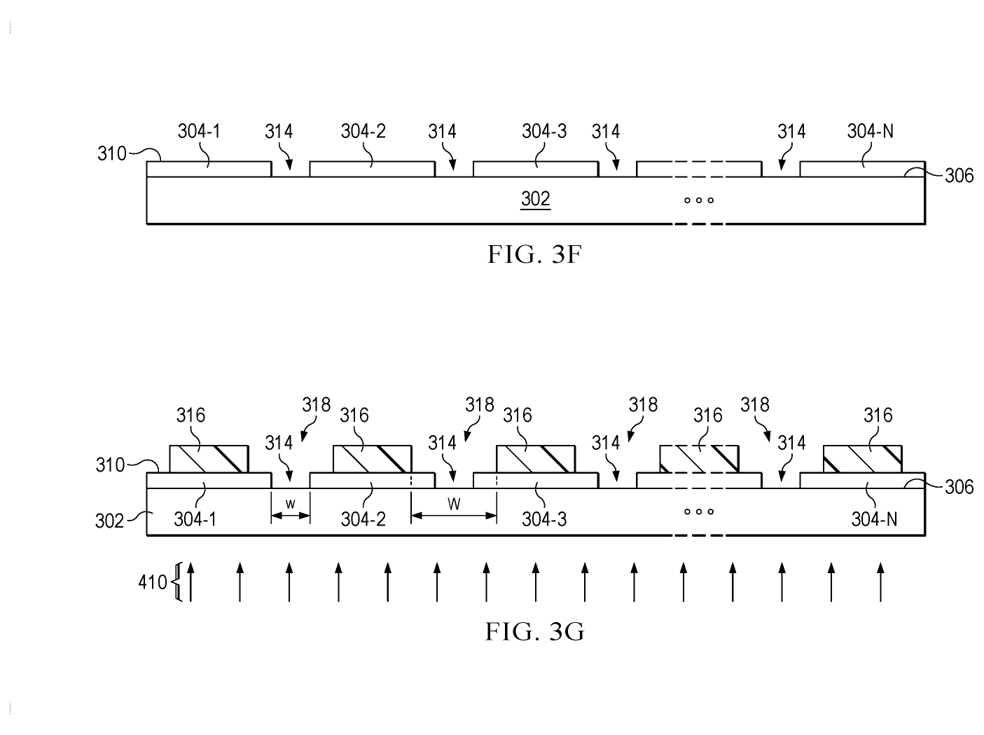

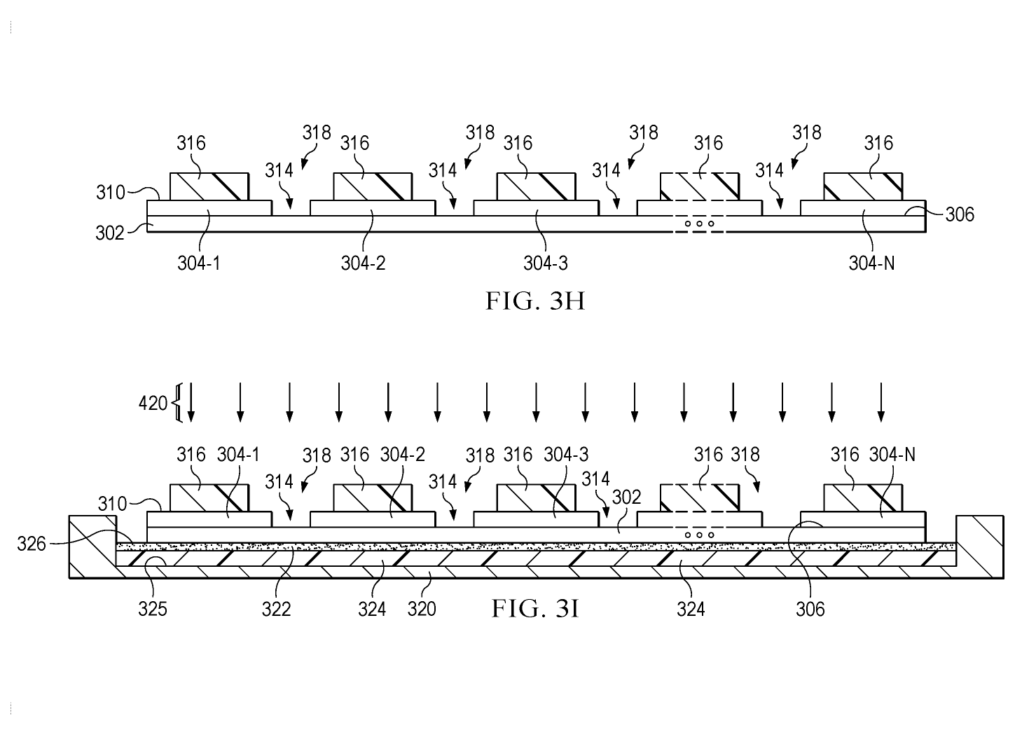

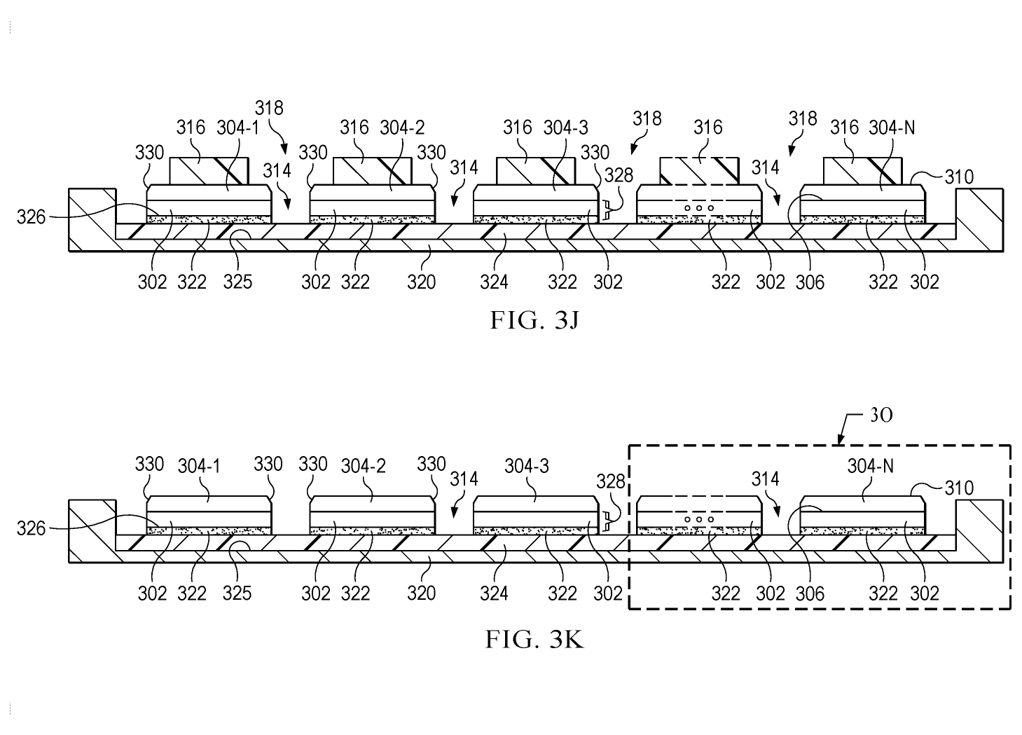

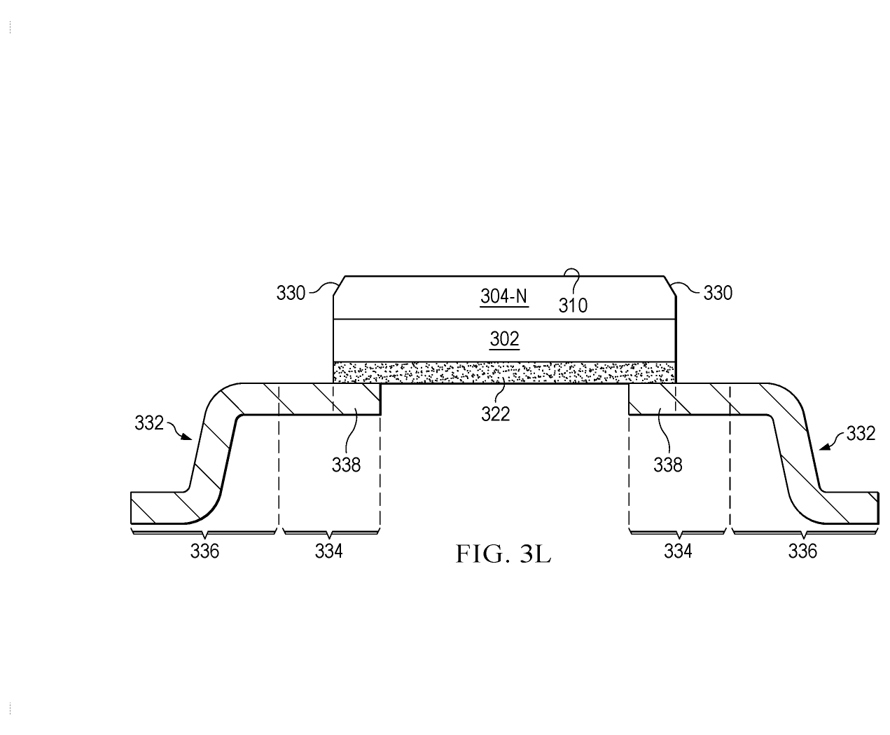

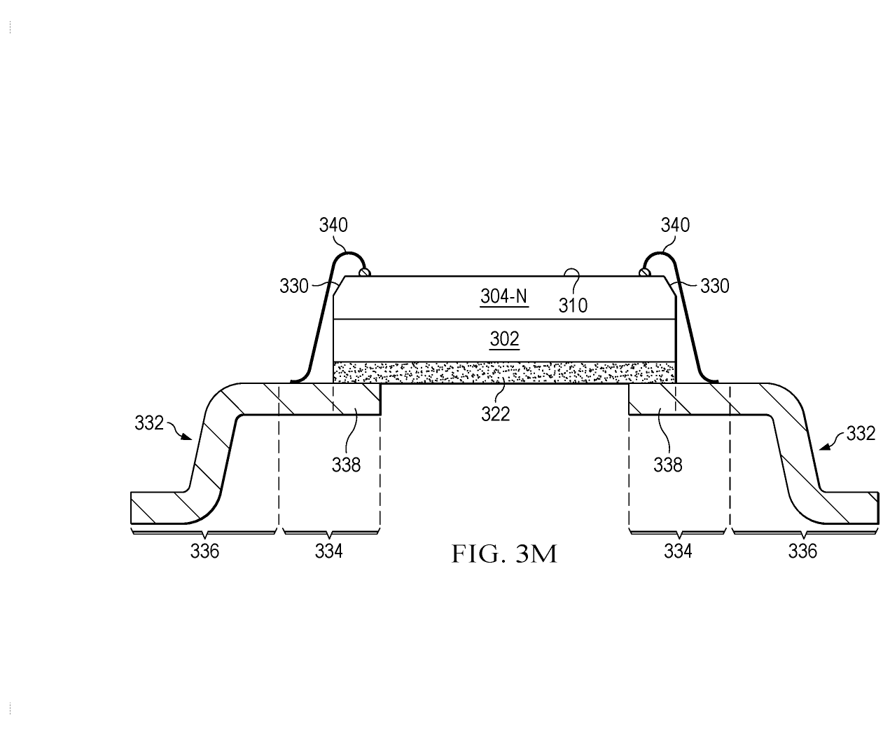

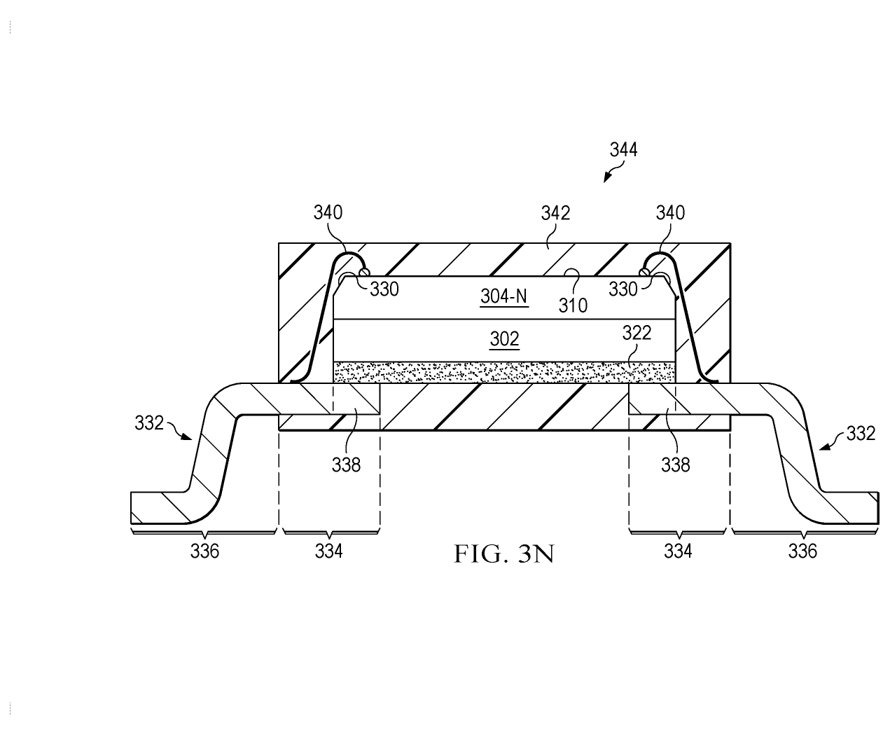

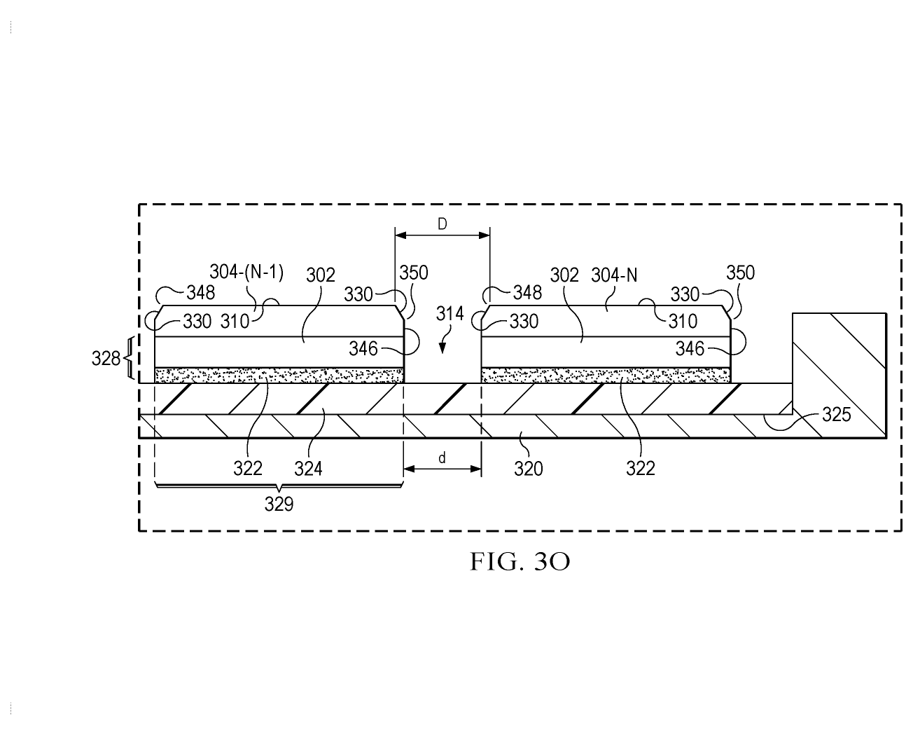

FIG. 2 is a block diagram flow chart explaining an example fabrication process 200 and FIGS. 3A-3O illustrate the example fabrication process associated with the formation of the example electronic device 100A illustrated in FIGS. 1A and 1B. Though depicted sequentially as a matter of convenience, at least some of the actions shown can be performed in a different order and/or performed in parallel. Alternatively, some implementations may perform only some of the actions shown. Still further, although the example illustrated in FIGS. 2 and 3A-3O is an example method, other methods and configurations are possible. It is understood that although the method illustrated in FIGS. 2 and 3A-3O depicts the fabrication process of a die assembly, the process applies to an array of die assemblies.

Referring to FIG. 2 and to FIGS. 3A-3O, the fabrication process 200 of the electronic device 100A illustrated in FIGS. 1A and 1B begins at 202 with a substrate (e.g., silicon wafer) 302, as illustrated in a top view in FIG. 3A and a cross-sectional view in FIG. 3B. At 204, an electronic device layer 304, prior to singulation, is formed one layer at a time on a first surface 306 the substrate 302 resulting in the configuration of FIG. 3C. The electronic device layer 304 includes scribe lines 307 for alignment purposes during singulation. In addition, the electronic device layer 304 is comprised of native oxides and metals (e.g., electronic circuit components). At 206, a first photoresist material layer 308 is formed on an active surface 310 of the electronic device layer 304 and is patterned and developed to expose first openings 312 in the first photoresist material layer 308 resulting in the configuration of FIG. 3D. The first photoresist material layer 308 can have a thickness that varies in correspondence with the wavelength of radiation used to pattern the first photoresist material layer 308. Specifically, the first photoresist material layer 308 has a thickness to allow the first openings 312 to be no wider than the scribe lines 307 on the electronic device layer 304. This protects the electronic device layer 304 during singulation (e.g., dicing). The first photoresist material layer 308 may be formed over the electronic device layer 304 via spin-coating or spin casting deposition techniques, selectively irradiated (e.g., via deep ultraviolet (DUV) irradiation) and developed to form the first openings 312.

At 208, the configuration in FIG. 3D undergoes a first dicing process via a dicing device (e.g., plasma laser dicing process) 400 to form device layer (first) openings 314 along the scribe lines 307 of the electronic device layer 304, resulting in the configuration of FIG. 3E. Specifically, the electronic device layer 304 is singulated along the scribe lines 307 to form individual dies 304-1, 304-2, 304-3,…304-N (collectively 304-N) on the substrate 302. The first dicing process 400 is an oxygen (O₂) based plasma laser process that dices through or singulates only the electronic device layer 304 and has a duration of approximately 4-10 minutes. During the first dicing process 400, the electronic device layer 304 is etched at a rate of approximately one-half micrometer per minute. In addition, approximately one micron of the first photoresist material layer 308 is removed for every 0.5 microns of etch depth in the electronic device layer 304. At 210, the first photoresist material layer 308 is removed, resulting in the configuration of FIG. 3F.

At 212, a second photoresist material layer 316 is formed over the active surface 310 of the individual dies 304-N and is patterned and developed to form second openings 318, resulting in the configuration of FIG. 3G. The second photoresist material layer 316 is patterned and developed such that the second openings 318 are centered over the device layer openings 314 between the individual dies 304-N, but have a width W that is greater than a width w of the device layer openings 314. The width W of the second openings 318 is wide enough to allow the substrate 302 to be fully diced in a subsequent dicing process. The second photoresist material layer 316 can have a thickness that varies in correspondence with the wavelength of radiation used to pattern the second photoresist material layer 316. Specifically, the thickness of the second photoresist material layer 316 is such that the width W of the second openings 318 is greater that the width w of the device layer openings 314 between the individual dies 304-N. In addition, the thickness of the second photoresist material layer 316 can vary based on the thickness of the isolation layer 120 described above. Still further, the thickness of the second photoresist material layer 316 can be approximately twice as thick as the thickness of the first photoresist material layer 308. The second photoresist material layer 316 may be formed over the individual dies 304-N via spin-coating or spin casting deposition techniques, selectively irradiated (e.g., via deep ultraviolet (DUV) irradiation) and developed to form the second openings 318.

At 214, the configuration of FIG. 3G undergoes a back grinding process 410 to remove a portion of the substrate 302 to achieve a desired thickness of the substrate 302, resulting in the configuration of FIG. 3H. At 216, the configuration of FIG. 3H is placed into a framed substrate (e.g., wafer) ring 320, where the framed substrate ring 320 includes an isolation layer (e.g., die attach film) 322 disposed on a dicing tape layer 324, which is formed on a bottom surface 325 of the framed substrate ring 320. Specifically, the configuration of FIG. 3H is placed on the isolation layer 322 such that a second surface 326 of the substrate 302 is in contact with the isolation layer 322, resulting in the configuration of FIG. 3I. At 218, the configuration of FIG. 3I undergoes a second dicing process via the dicing device (e.g., plasma laser dicing process) 420 to form substrate (second) openings 328 in the substrate 302 and in the isolation layer 322 where the substrate openings 328 are aligned with the device layer openings 314. As a result, both the substrate 302 and the isolation layer 322, along with the device layer 304-N are singulated, resulting in the configuration of FIG. 3J. Thus, after the second dicing process 420, the singulated dies 304-N, the singulated substrate 302, and the singulated isolation layer 322 form die assemblies 329.

The second dicing process 420 is two-phase process that repeats until the etching process is completed and has a duration of duration of approximately 5-10 minutes. The first phase is a sulfur hexafluoride (SF6) plasma etch. The second phase is a deposition step that deposits an inert passivation layer (e.g., octafluorocyclobutane C4F8) on the substrate 302 to protect the substrate 302 from chemical attack during the etching process. The etch/deposition phases each last for several seconds and are repeated a number of times until the etching process is completed (e.g., duration of approximately 5-10 minutes). For every approximately 300 microns of the substrate 302 that is etched (removed), only approximately one micron of the electronic device layer 304 is affected. Since the substrate 302 is only approximately 100 microns thick, only a very small layer of the device layer 304 is affected. Specifically, a taper 330 is formed on each side of the individual dies 304-N as a result of the second dicing process 420. The portion of the device layer 304 where the taper 330 is formed is primarily comprised of the native oxides which provides protection to the metals in the device layer 304 during the second dicing process 420. At 220, the second photoresist material layer 316 is removed, resulting in the configuration of FIG. 3K.

At 222, the die assemblies 329, which include the singulated dies 304-N, the singulated substrate 302, and the singulated isolation layer 322, are picked from the dicing tape 324 and placed on a leadframe 332, where the leadframe comprises inner leads 334 and outer leads 336. Specifically, the die assemblies 329 are placed on the leadframe 332 such that the isolation layer 322 is placed on die mounting pads 338 of the inner leads 334 of the leadframe 332, resulting in the configuration of FIG. 3L. At 224, wire bonds 340 are attached from the active surface 310 of the die 304-N to the inner leads 334 thereby providing an electrical connection between the die 304-N and the leadframe 332, resulting in the configuration of 3M. At 226, a mold compound 342 is formed over and encapsulates the die assembly 329, the inner leads 334 including the die mounting pads 338, and the wire bonds 340, resulting in the electronic device 344 illustrated in FIG. 3N.

FIG. 3O is a close-up cross-sectional view of adjacent die assemblies 329 comprising dies 304-(N-1), 304-N that illustrates a configuration of the taper 330 on adjacent dies 304-(N-1), 304-N. The taper 330 is configured to extend from the active surface 310 of the die 304-N down each side 346 of the die 304-N. In some examples, the taper 330 can extend approximately one-quarter to one-third down each side 346 of the die. In addition, the taper 330 is configured such that a distance D between first end points 348 of the taper 330 of adjacent dies 304-N is greater than a distance d between second end points 350 of the taper 330 of adjacent die 304-N. In some examples, the distance D between adjacent first end points 348 can range from approximately 6 microns to 10 microns. The distance d between adjacent second end points 350 can range from approximately 4 microns to 7 microns.

As mentioned above, the second dicing process 420 produces the taper 330 on the dies 304-N. Specifically, in order to achieve scribe lines of approximately 10 microns wide or less and to dice entirely through the substrate 302 and the isolation layer 322, a thickness of the second photoresist material layer 316 must have a thickness (e.g., at least 50 microns) to obtain the second openings 318 that are wider than the device layer openings 314. During the second dicing process 420, as the dicing device moves in a direction to fully dice the substrate 302 and the isolation layer 322, the dicing device creates the taper 330 on the sides of each die 304-N. Since the electronic device layer 304 includes the native oxides, the native oxides protect the electronic device layer 304, and hence the active surface 310 of the dies 304-N during the second etching process 420.

Thus, the two-step dicing process is a singulation process that utilizes a first photoresist material layer to dice the device layer into induvial dies and then utilizes a second photoresist material layer and leverages the native oxides in the device layer to dice the remaining layers, i.e., substrate and isolation layer. The singulation process achieves small scribe lines (e.g., less than 10 microns), thereby allowing larger dies to be packaged into smaller IC packages.

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite "a," "an," "a first," or "another" element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. A method comprising:
forming an electronic device layer on a first surface of a substrate;
forming first openings in only the electronic device layer to singulate the device layer into individual dies;
performing a back grinding process on a second surface of the substrate;
placing the substrate on an isolation layer;
forming second openings in the substrate and the isolation layer to form die assemblies comprising the individual dies, the substrate, and the isolation layer;
placing the die assemblies on a leadframe; and
forming a mold compound over the die assemblies.

2. The method of claim 1, wherein forming first openings includes performing a first dicing process to form device layer openings along scribe lines of the electronic device layer.

3. The method of claim 2, wherein forming second openings includes performing a second dicing process to form substrate openings in the substrate and in the isolation layer, and forming a taper on each individual die that extends from an active surface to each side of the individual dies, the substrate opening being aligned with the device layer openings.

4. The method of claim 1, wherein forming second openings includes performing a dicing process to form substrate openings in the substrate and in the isolation layer, and forming a taper on each individual die that extends from an active surface to each side of the individual dies, the substrate openings being aligned with the first opening.

5. The method of claim 4, wherein forming first openings includes performing a first dicing process to form device layer openings along scribe lines of the electronic device layer, and wherein the dicing process to from the substrate openings is a second dicing process.

6. The method of claim 1, wherein prior to forming first openings in only the electronic device layer to form individual dies, the method comprising:
forming a first photoresist material layer on an active surface of the electronic device layer; and
patterning and developing the first photoresist material layer to form first openings in the first photoresist material layer.

7. The method of claim 6, wherein forming first openings in only the electronic device layer to form individual dies includes performing a first dicing process to form device layer openings along scribe lines to singulate the electronic device layer into the individual dies.

8. The method of claim 7, wherein the scribe lines are less than 10 microns wide.

9. The method of claim 8 further comprising removing the first photoresist material layer.

10. The method of claim 9, wherein prior to performing a back grinding process on a second surface of the substrate, the method comprising:
forming a second photoresist material layer on the active surface of the electronic device layer; and
patterning and developing the second photoresist material layer to form second openings in the second photoresist material layer.

11. The method of claim 10, wherein the second openings in the second photoresist material layer are centered over the device layer openings, the second openings in the second photoresist material layer have a width greater than a width of the device layer openings.

12. The method of claim 11, wherein placing the substrate on an isolation layer includes providing a framed substrate ring having a dicing tape layer formed on a bottom surface of the framed substrate ring, forming the isolation layer on the dicing tape layer, and placing the substrate on the isolation layer such that the second surface of the substrate is in contact with the isolation layer.

13. The method of claim 12, wherein forming second openings in the substrate and the isolation layer to form die assemblies comprising the individual dies, the substrate, and the isolation layer includes performing a second dicing process to form substrate openings in the substrate and in the isolation layer to singulate both the substrate and the isolation layer to form the die assemblies.

14. The method of claim 13 further comprising removing the second photoresist material layer.

15. The method of claim 14, wherein the second dicing process further includes forming a taper extending from the active surface of the individual dies to each side of the individual dies.

16. The method of claim 15, wherein the leadframe includes inner leads and wherein placing the die assemblies on a leadframe includes placing the die assemblies on die mounting pads of the inner leads.

17. The method of claim 16, wherein prior to forming a mold compound over the die assemblies, the method comprising attaching wire bonds from an active surface of the individual dies to the inner leads.

18. The method of claim 17, wherein forming a mold compound over the die assemblies further includes forming the mold compound over the inner leads and the wire bonds.

19. An electronic device comprising:
a leadframe having inner leads;
a die assembly attached to the inner leads, the die assembly including a substrate, a die attached to a first surface of the substrate, and an isolation layer attached to a second surface of the substrate, the die having a taper extending from an active surface of the die down each side of the die; and
a mold compound encapsulating the die assembly.

20. The electronic device of claim 19, wherein the taper extends from an active surface of the die approximately one-quarter to one third of the way down each side of the die.

21. The electronic device of claim 20, wherein the isolation layer is a die attach film.

22. The electronic device of claim 21, wherein the inner leads include die mounting pads and wherein the die attach film attaches to the die mounting pads.

23. The electronic device of claim 22 further comprising wire bonds attached to the active surface of the die and to the inner leads of the leadframe.

24. The electronic device of claim 23, wherein the leadframe further comprises outer leads attached to the inner leads.
